(19) United States
(12) Patent Application Publication
(10) Pub. No.: US 2022/0158394 A1
(43) Pub. Date: May 19, 2022

(54) IN-VEHICLE ELECTRICAL DEVICE

(71) Applicant: Mitsubishi Electric Corporation, Tokyo (JP)

(72) Inventors: Toshihiro KURODA, Tokyo (JP); Kazuto Kikuchi, Tokyo (JP)

(73) Assignee: Mitsubishi Electric Corporation, Tokyo (JP)

(21) Appl. No.: 17/386,006

(22) Filed: Jul. 27, 2021

(30) Foreign Application Priority Data
Nov. 16, 2020 (JP) 2020-189972

(51) Int. Cl. H01R 13/73; H01R 13/52

(52) U.S. Cl. CPC H01R 13/73; H01R 2201/26; H01R 13/5202

(57) ABSTRACT

To provide an in-vehicle electrical device which can ensure required strength or waterproof performance while suppressing an increase in product weight and an increase in the number of assembly processes and also can suppress a housing breakage caused by corrosion. The in-vehicle electrical device includes a housing which houses a substrate or a unit; and a sheet metal assembly which, being fixed to one surface of the housing, has a sheet metal which is a pressed part, an interlock connector disposed on one surface of the sheet metal, and a metallic sheet formed extending laterally of the interlock connector, wherein the interlock connector is retained on the sheet metal by caulking the sheet metal and the metallic sheet, and a caulked point of both the sheet metal and the metallic sheet is formed raised outwardly of the housing.

### BACKGROUND OF THE INVENTION

### Field of the Invention

The present application relates to the field of an in-vehicle electrical device.

### Description of the Related Art

As an in-vehicle electrical device mounted in an electric vehicle or a hybrid car is sometimes forced to be disposed in a space under harsh environmental conditions, it has heretofore been required to protect a high-voltage portion. Also, the in-vehicle electrical device, as it also has a product which may entail various risks, requires a high standard for dust-, drip-, or corrosion-proof performance in a limited space. In response to this kind of requirement, a structure has heretofore been commonly developed wherein a recessed portion in which water or the like is likely to stand is injected with a filler, for example, when assembling an in-vehicle electrical device, such as a power converter, or when assembling the in-vehicle electrical device to a vehicle, thus improving dust-, drip-, or corrosion-proof performance. Also, a structure of an air cushion has heretofore been disclosed whose configuration is such that a recessed portion in which water or the like is likely to stand is injected and infilled with a filler, thereby improving corrosion resistance (for example, refer to PTL 1). Also, in general, a vehicle has a high requirement for a reduction in weight and size in terms of a reduction of environmental burdens.

[PTL 1] JP-A-2010-71378

In a heretofore known in-vehicle electrical device disclosed in, for example, PTL 1, however, an improvement in corrosion resistance is sought by injecting and infilling the recessed portion, in which water or the like is likely to stand, with a filler, so that there are problems, such as an increase in product weight and an increase in the number of assembly processes, caused by the filler injection. Also, in a limited space, the in-vehicle electrical device, while being required to ensure required strength or waterproof performance, requires a high standard for dust-, drip-, or corrosion-proof performance.

### SUMMARY OF THE INVENTION

The present application has been made to solve the above problem, and an object of the present application is to provide an in-vehicle electrical device which can ensure required strength or waterproof performance while suppressing an increase in product weight and an increase in the number of assembly processes and also can suppress a housing breakage caused by corrosion.

An in-vehicle electrical device disclosed in the present application includes a housing which houses a substrate or a unit; and a sheet metal assembly which, being fixed to one surface of the housing, has a sheet metal which is a pressed part, an interlock connector disposed on one surface of the sheet metal, and a metallic sheet formed extending laterally of the interlock connector, wherein the interlock connector is retained on the sheet metal by caulking the sheet metal and the metallic sheet, and a caulked point of both the sheet metal and the metallic sheet is formed raised outwardly of the housing.

Also, an in-vehicle electrical device disclosed in the present application includes a housing which houses a substrate or a unit; and a sheet metal assembly which, being fixed to one surface of the housing, has a sheet metal which is a pressed part, an interlock connector disposed on one surface of the sheet metal, and a metallic sheet formed extending laterally of the interlock connector, wherein the interlock connector is retained on the sheet metal by caulking the sheet metal and the metallic sheet, and a caulked point of both the sheet metal and the metallic sheet is formed recessed as seen from outside the housing and is covered with a product label or a caution label.

According to the in-vehicle electrical device disclosed in the present application, it is possible to obtain the in-vehicle electrical device which can ensure required strength or waterproof performance while suppressing an increase in product weight and an increase in the number of assembly processes and also can suppress a housing breakage caused by corrosion.

The foregoing and other objects, features, aspects, and advantages of the present application will become more apparent from the following detailed description of the present application when taken in conjunction with the accompanying drawings.

### BRIEF DESCRIPTION OF THE DRAWINGS

FIG. 1 is a perspective view showing an in-vehicle electrical device according to a first embodiment.

FIG. 2 is a perspective view showing a sheet metal assembly of the in-vehicle electrical device according to the first embodiment.

FIG. 3 is a top view showing the sheet metal assembly of the in-vehicle electrical device according to the first embodiment.

FIG. 4 is a sectional view along the line A-A of FIG. 3.

FIG. 5 is a view showing a state in which the sheet metal assembly according to the first embodiment is pressed.

FIG. 6 is a top view showing a sheet metal assembly of an in-vehicle electrical device according to a second embodiment.

FIG. 7 is a top view showing the sheet metal assembly of the in-vehicle electrical device according to the second embodiment.

FIG. 8 is a sectional view along the line B-B of FIG. 7.

### DETAILED DESCRIPTION OF THE PREFERRED EMBODIMENTS

### First Embodiment

A description will hereinafter be given, based on the drawings, of a first embodiment. In the individual drawings, identical signs show identical or equivalent portions.

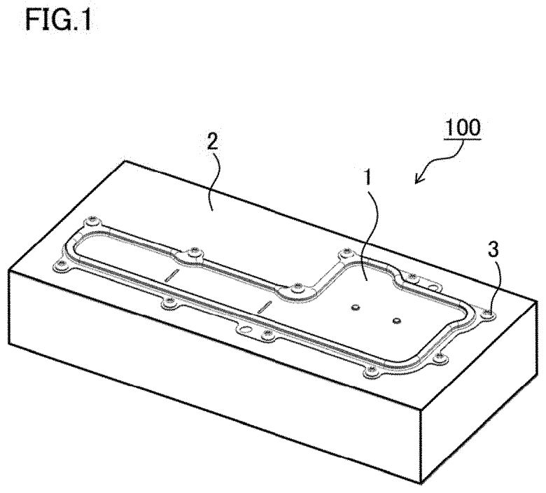

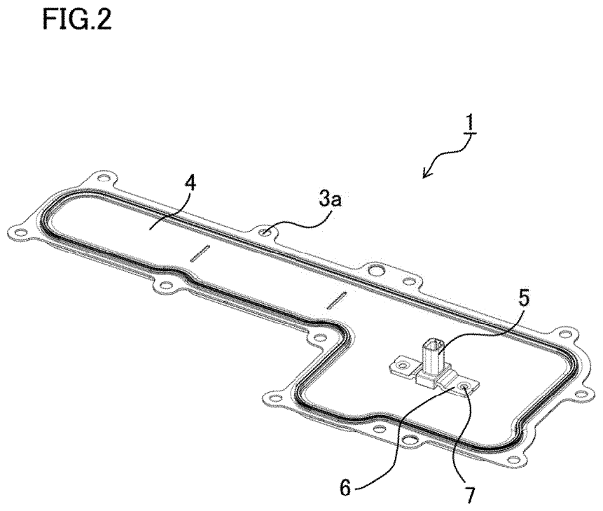

FIG. 1 is a perspective view showing an in-vehicle electrical device according to the first embodiment, and FIG. 2 is a perspective view showing a sheet metal assembly of the in-vehicle electrical device according to the first embodiment.

As shown in FIG. 1, an in-vehicle electrical device 100 according to the first embodiment has a sheet metal assembly 1 fixed by a screw 3 to a housing 2 inside which a unit (not shown) is housed. Also, as shown in FIG. 2, the sheet metal assembly 1 of the in-vehicle electrical device 100 according to the first embodiment has a sheet metal 4 and an interlock connector 5. The interlock connector 5 is a molded part with which a small sheet metal 6 is integrated. The small sheet metal 6 is retained on the sheet metal 4 by a caulked point 7.

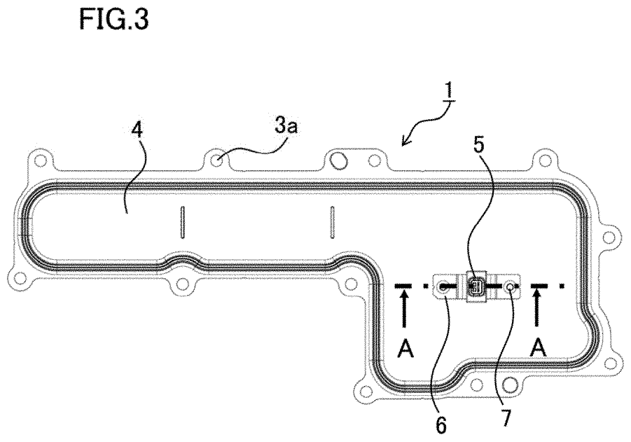

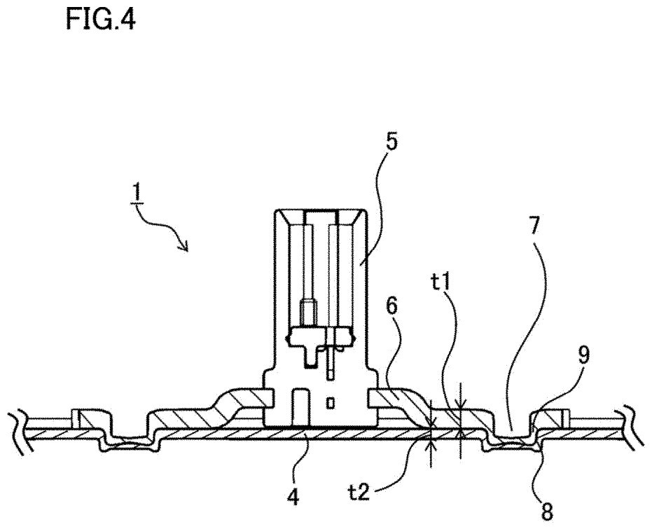

FIG. 3 is a top view showing the sheet metal assembly of the in-vehicle electrical device according to the first embodiment, and FIG. 4 is a sectional view along the line A-A of FIG. 3. FIGS. 2 and 3 are views of the sheet metal assembly 1 as seen from inside the housing 2 to which it is fixed, and the sheet metal assembly 1 is fixed to the housing 2 with the interlock connector 5 directed downward and opposed to the housing.

The interlock connector 5 is mated with a connector (not shown) mounted on a substrate (not shown) inside the housing 2. The sheet metal 4, being a pressed part containing, for example, aluminum, has a hole of screw 3a through which to secure the sheet metal 4 to the housing 2.

The interlock connector 5 is fixed to the sheet metal assembly 1, whereby at the same time as when the sheet metal assembly 1 is removed from the housing 2, the interlock connector 5 is unmated from the connector mounted on the substrate, enabling the function of electronics inside the housing 2 to stop.

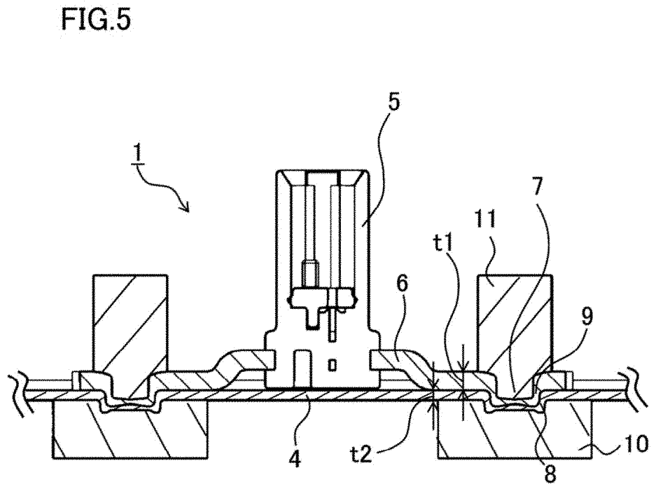

FIG. 4 shows the sheet metal assembly 1 before assembled to the housing 2 of the in-vehicle electrical device 100. As shown in FIG. 4, the caulked point 7, being a non-through caulking into which two metals, the sheet metal 4 and the small sheet metal 6, are pressed together, is such that the two metals are joined together so as to be formed raised outwardly of the housing 2. FIG. 5 is a view showing a state in which the sheet metal assembly 1 according to the first embodiment is pressed, and specifically, showing a state in which the sheet metal 4 and the small sheet metal 6 are caulked by a die 10 and punch 11.

When caulking the sheet metal 4 and the small sheet metal 6, the thickness of sheet metal on the punch 11 side is made greater than that on the die 10 side, thereby enabling a reduction in the respective rates of decrease in sheet thickness of a caulked point of decreased thickness on sheet metal 8 and a caulked point of decreased thickness on small sheet metal 9. That is, when the sheet thickness of the small sheet metal 6 is taken as t1 and that of the sheet metal 4 as t2, t1 greater in thickness of sheet metal is disposed on the punch 11 side instead of on the die 10 side, and thereby it is possible to form the caulked point 7 whose raised outer side is kept low in the rate of decrease in sheet thickness.

As the caulked point 7 is non-through, it does not happen that this will lead to a decrease in dust-, drip-, or corrosion-proof performance, and also, the caulked point 7 is formed raised outwardly of the housing 2, thereby enabling a foreign substance, such as a liquid, not to stand in the caulked point 7, and it is possible to suppress corrosion of the caulked point 7 in the housing 2.

In the sheet metal assembly 1 of the in-vehicle electrical device 100 according to the first embodiment, the sheet metal 4 and the small sheet metal 6 which is a metallic sheet decrease in their respective sheet thicknesses by being caulked, but the rate of decrease in sheet thickness of the sheet metal 4 on the raised outer side of the caulked point 7 is lower than that of the small sheet metal 6 which is a metallic sheet. According to the sheet metal assembly 1 of the in-vehicle electrical device 100 according to the first embodiment, it is possible to suppress the rate of decrease in sheet thickness when caulking, and thus possible to enhance the resistance to corrosion fracture caused by external circumstances.

When pressing the sheet metal assembly 1 of the in-vehicle electrical device 100 according to the first embodiment, the sheet metal 4 and the small sheet metal 6 may be caulked with an oil excellent in antirust effect applied thereto. Thereby, it is possible to enhance the resistance to corrosion fracture caused by external circumstances.

Also, a seal material in one of a liquid, a solid, or a sheet state is disposed between the small sheet metal 6 formed integral with the interlock connector 5 and the sheet metal 4. It is possible, by disposing (the seal material) and caulking, to enhance the resistance to corrosion fracture caused by external circumstances or to enhance adhesion.

Also, when pressing the sheet metal assembly 1 of the in-vehicle electrical device 100 according to the first embodiment, the sheet metal greater in sheet thickness than on the die 10 side is disposed on the punch 11 side, but the caulked point 7 only has to be formed so as to be non-through, and when different in-vehicle constrains occur, caulking may be performed with the thickness of sheet metal on the die 10 side made greater than on the punch 11 side.

As above, the in-vehicle electrical device 100 of the first embodiment includes the housing 2 which houses the substrate or the unit; and the sheet metal assembly 1 which, being fixed to one surface of the housing 2, has the sheet metal 4 which is a pressed part, the interlock connector 5 disposed on one surface of the sheet metal 4, and the small sheet metal 6 which, being a metallic sheet, is formed extending laterally of the interlock connector 5, wherein the interlock connector 5 is retained on the sheet metal 4 by caulking the sheet metal 4 and the small sheet metal 6 which is a metallic sheet, and the caulked point 7 of both the sheet metal 4 and the small sheet metal 6 which is a metallic sheet is formed raised outwardly of the housing 2.

According to the in-vehicle electrical device 100 of the first embodiment, the sheet metal 4 and the small sheet metal 6 are caulked so as to be non-through, and at the same time, the caulked point 7 is formed raised outwardly of the housing 2, thereby enabling a foreign substance, a liquid, or the like not to stand in the caulked point 7 even when affected by, for example, environmental impact such as rain, and it is possible to prevent dust-, drip-, or corrosion-proof performance from decreasing due to corrosion. Also, as there is no need to inject a filler, it is possible to obtain the in-vehicle electrical device 100 which can suppress an increase in product weight, an increase in the number of assembly processes, and an increase in cost. Furthermore, the in-vehicle electrical device 100 according to the first embodiment is such that it is possible, while ensuring required strength or waterproof performance in a limited space, to suppress a breakage of the caulked point 7 of the housing 2 caused by corrosion.

### Second Embodiment

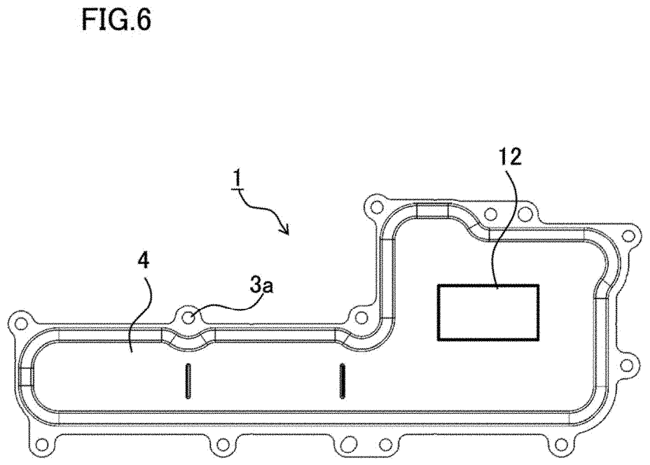

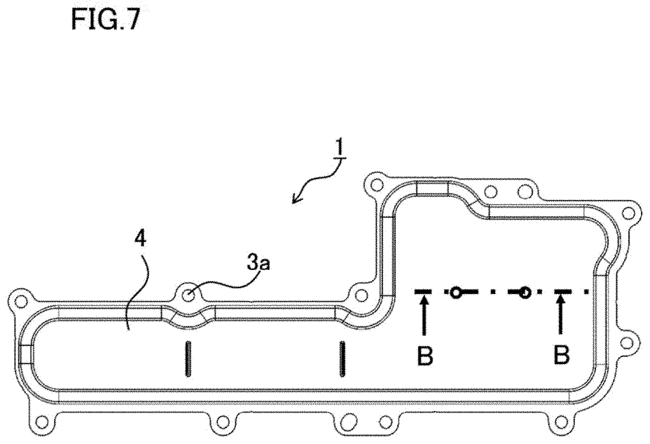

FIGS. 6 and 7 are top views each showing a sheet metal assembly of an in-vehicle electrical device according to a second embodiment.

A description will hereinafter be given, centering on portions differing from in the first embodiment, of an in-vehicle electrical device 100 according to the second embodiment.

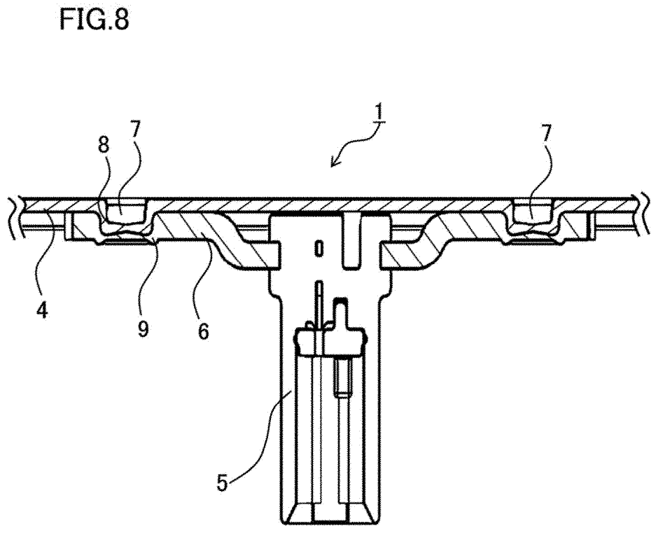

As shown in FIG. 6, a sheet metal assembly 1 of the in-vehicle electrical device 100 according to the second embodiment is such that a region including a caulked point 7 is covered with a product label 12 or a caution label. FIG. 7 shows a state in which there does not exist the product label 12 or caution label in the structure of FIG. 6. Also, FIG. 8 is a sectional view along the line B-B of FIG. 7.

As shown in FIG. 8, the sheet metal assembly 1 of the in-vehicle electrical device 100 according to the second embodiment has a sheet metal 4 which is a pressed part, an interlock connector 5 disposed on one surface of the sheet metal 4, and a small sheet metal 6 which, being a metallic sheet, is formed extending laterally of the interlock connector 5. The interlock connector 5 is retained on the sheet metal 4 by caulking the sheet metal 4 and the small sheet metal 6 which is a metallic sheet, and the caulked point 7 of both the sheet metal 4 and the small sheet metal 6 which is a metallic sheet is formed recessed as seen from outside the housing 2.

The sheet metal assembly 1 of the in-vehicle electrical device 100 according to the second embodiment shows a structure of when the caulked point 7 formed raised outwardly of the housing 2 cannot be formed due to different in-vehicle constrains. The sheet metal assembly 1 of the in-vehicle electrical device 100 according to the second embodiment has the caulked point 7 formed recessed as seen from outside the housing 2, but as shown in FIG. 6, the whole of the caulked point 7 recesses is covered with the product label 12 or a caution label. Then, the sheet metal assembly 1 of the in-vehicle electrical device 100 according to the second embodiment is fixed to one surface of the housing 2 which houses a substrate or a unit, and is secured by a screw 3, in the same way as in the first embodiment. Also, in the sheet metal assembly 1 of the in-vehicle electrical device 100 according to the second embodiment as well, in the same way as in the first embodiment, the caulked point 7 kept low in a rate of decrease in sheet thickness by caulking is formed so that the rate of decrease in sheet thickness of a caulked point of decreased thickness on sheet metal 8 of the sheet metal 4 is lower than that of a caulked point of decreased thickness on small sheet metal 9 of the small sheet metal 6.

As above, the in-vehicle electrical device 100 of the second embodiment includes the housing 2 which houses the substrate or the unit; and the sheet metal assembly 1 which, being fixed to one surface of the housing 2, has the sheet metal 4 which is a pressed part, the interlock connector 5 disposed on one surface of the sheet metal 4, and the small sheet metal 6 which, being a metallic sheet, is formed extending laterally of the interlock connector 5, wherein the interlock connector 5 is retained on the sheet metal 4 by caulking the sheet metal 4 and the small sheet metal 6 which is a metallic sheet, and the caulked point 7 of both the sheet metal 4 and the small sheet metal 6 which is a metallic sheet is formed recessed as seen from outside the housing 2 and is covered with the product label 12 or a caution label.

According to the in-vehicle electrical device 100 of the second embodiment, even when the caulked point 7 formed raised outwardly of the housing 2 cannot be formed due to different in-vehicle constraints, and the caulked point 7 is formed recessed as seen from outside the housing 2, the caulked point 7 is covered with the product label 12 or a caution label, thereby enabling a foreign substance, a liquid, or the like not to stand in the recessed portion on the outer side of the housing 2, and it is possible to suppress corrosion. Also, the product label 12 or a caution label is used, thereby removing the use of unnecessary components, so that it is possible to suppress an increase in product weight.

As above, according to the in-vehicle electrical device 100 of the first or second embodiment, a description has been given, as a component retained on the sheet metal assembly 1, of the case of the interlock connector 5 formed integral with the small sheet metal 6 which is a metallic sheet, but the component only has to be one which can be joined by caulking, and may also be, for example, a cable clamp, a radiator plate, or a heat sink instead of the interlock connector 5.

Although the present application is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments.

It is therefore understood that numerous modifications which have not been exemplified can be devised without departing from the scope of the present application. For example, at least one of the constituent components may be modified, added, or eliminated. At least one of the constituent components mentioned in at least one of the preferred embodiments may be selected and combined with the constituent components mentioned in another preferred embodiment.

What is claimed is:

1. An in-vehicle electrical device, comprising:
a housing which houses a substrate or a unit; and
a sheet metal assembly which, being fixed to one surface of the housing, has a sheet metal which is a pressed part, an interlock connector disposed on one surface of the sheet metal, and a metallic sheet formed extending laterally of the interlock connector, wherein
the interlock connector is retained on the sheet metal by caulking the sheet metal and the metallic sheet, and
a caulked point of both the sheet metal and the metallic sheet is formed raised outwardly of the housing.

2. The in-vehicle electrical device according to claim 1, wherein
when the substrate is housed in the housing,
the sheet metal assembly has the interlock connector fixed opposed to the housing and secured to the housing by a screw, and
the interlock connector is mated with a connector mounted on the substrate inside the housing.

3. The in-vehicle electrical device according to claim 1, wherein
the sheet metal and the metallic sheet decrease in their respective sheet thicknesses by being caulked, and
a rate of decrease in sheet thickness of the sheet metal on the raised outer side of the caulked point is lower than that of the metallic sheet.

4. The in-vehicle electrical device according to claim 1, wherein
an oil is applied to the caulked point of both the sheet metal and the metallic sheet.

5. The in-vehicle electrical device according to claim 1, wherein
a seal material in one of a liquid, a solid, or a sheet state is disposed between the sheet metal and the metallic sheet of the interlock connector.

6. The in-vehicle electrical device according to claim 1, wherein
the interlock connector is a molded part formed integral with the metallic sheet.

7. The in-vehicle electrical device according to claim 2, wherein
the sheet metal and the metallic sheet decrease in their respective sheet thicknesses by being caulked, and
a rate of decrease in sheet thickness of the sheet metal on the raised outer side of the caulked point is lower than that of the metallic sheet.

8. The in-vehicle electrical device according to claim 2, wherein
an oil is applied to the caulked point of both the sheet metal and the metallic sheet.

9. The in-vehicle electrical device according to claim 2, wherein
a seal material in one of a liquid, a solid, or a sheet state is disposed between the sheet metal and the metallic sheet of the interlock connector.

10. The in-vehicle electrical device according to claim 2, wherein
the interlock connector is a molded part formed integral with the metallic sheet.

11. The in-vehicle electrical device according to claim 3, wherein
an oil is applied to the caulked point of both the sheet metal and the metallic sheet.

12. The in-vehicle electrical device according to claim 3, wherein
a seal material in one of a liquid, a solid, or a sheet state is disposed between the sheet metal and the metallic sheet of the interlock connector.

13. The in-vehicle electrical device according to claim 3, wherein
the interlock connector is a molded part formed integral with the metallic sheet.

14. The in-vehicle electrical device according to claim 4, wherein
a seal material in one of a liquid, a solid, or a sheet state is disposed between the sheet metal and the metallic sheet of the interlock connector.

15. The in-vehicle electrical device according to claim 4, wherein
the interlock connector is a molded part formed integral with the metallic sheet.

16. The in-vehicle electrical device according to claim 5, wherein
the interlock connector is a molded part formed integral with the metallic sheet.

17. An in-vehicle electrical device, comprising:
a housing which houses a substrate or a unit; and
a sheet metal assembly which, being fixed to one surface of the housing, has a sheet metal which is a pressed part, an interlock connector disposed on one surface of the sheet metal, and a metallic sheet formed extending laterally of the interlock connector, wherein
the interlock connector is retained on the sheet metal by caulking the sheet metal and the metallic sheet, and
a caulked point of both the sheet metal and the metallic sheet is formed recessed as seen from outside the housing and is covered with a product label or a caution label.
